(19) United States
(12) Patent Application Publication
(10) Pub. No.: US 2012/0261820 A1
(43) Pub. Date: Oct. 18, 2012

(54) ASSEMBLY OF STACKED DEVICES WITH SEMICONDUCTOR COMPONENTS

(75) Inventor: Julien Vittu, Villard de lans (FR)

(73) Assignee: STMICROELECTRONICS (GRENOBLE 2) SAS, Grenoble (FR)

(21) Appl. No.: 13/444,672

(22) Filed: Apr. 11, 2012

(30) Foreign Application Priority Data
Apr. 14, 2011 (FR) 1153274

(51) Int. Cl. H01L 25/07; H01L 21/98

(52) U.S. Cl. 257/738; 438/109; 257/E25.018; 257/E21.705

(57) ABSTRACT

A method for forming an assembly including, stacked on each other, first and second devices with semiconductor components including opposite conductive balls, this method including the steps of: a) forming, on the first device, at least one resin pattern, close to at least some of the conductive balls by a distance smaller than or equal to half the ball diameter, and of a height greater than the ball height; and b) bonding the second device to the first device, by using said at least one pattern to guide the balls of the second device towards the corresponding balls of the first device.

### BACKGROUND

### Technical

The present disclosure relates to a method for forming an assembly comprising, stacked on each other, first and second devices with semiconductor components comprising opposite conductive balls. It also relates to such an assembly.

### Description of the Related Art

FIG. 1 is a cross-section view schematically showing an assembly comprising stacked first and second devices with semiconductor components, respectively 1 (lower device) and 2 (upper device). Devices 1 and 2 each comprise a semiconductor chip, respectively 3 and 4, encapsulated in a package. Each of chips 3 and 4 is formed from a semiconductor substrate, for example, made of silicon. The substrates are generally thinned so that the chip thickness does not exceed between 100 and 200 μm. Such assemblies are generally designated in the art as PoPs, for “Package on Package”. As an example, lower chip 3 comprises a microprocessor, and upper chip 4 comprises a memory assembly to which the microprocessor can have access.

The package of device 1 comprises a support wafer 5 having chip 3 assembled on its upper surface. Wafer 5 has, in top view, a much greater surface area than chip 3. Wafer 5 is intended to support conductive balls enabling to connect chip 3 to upper device 2. Wafer 5 is generally made of an organic material and may comprise various metallization levels (for example, made of copper). The upper level comprises contacting areas (especially intended to receive the conductive balls). On the upper surface of wafer 5 are attached balls 7 intended to provide connections to upper device 2. In top view, balls 7 are arranged in a ring around chip 3. In this example, balls 9 are further attached to the lower surface of wafer 5, and are intended to provide connections to an external device, not shown, for example, a printed circuit board. Chip 3 is connected to contacting areas of wafer 5 by means of contact wires 11, for example, made of gold. The upper and lateral surfaces of chip 3, as well as contact wires 11, are embedded in a protection resin 13 forming the upper portion of the package of device 1. Resin 13 forms, with chip 3, an island resting on the central portion of wafer 5, between conductive balls 7. The package of upper device 2 is similar to the package of device 1. It comprises, in its lower portion, a support wafer 15 having chip 4 assembled on its upper surface, and, in its upper portion, a protection resin 17 in which are embedded the upper and lateral surfaces of chip 4 and contact wires providing the connections of chip 4 to wafer 15. On its lower surface side, wafer 15 comprises the metal contacting areas intended to be connected to conductive balls 7 providing the connections to device 1.

It should be noted that such an assembly can only be achieved if height Hb of balls 7 is greater than height Hr of the central island formed by resin 13 and chip 3. This is a limitation for this type of assembly when the number of balls 7 per surface area unit is desired to be increased (to increase the number of connections between devices 1 and 2 without increasing the surface area of support wafers 5 and 15). Indeed, to increase the number of balls per surface area unit, it is necessary to decrease the ball diameter, and accordingly to decrease height Hb. The number of balls 7 per surface area unit is thus limited by height Hr of the central island.

Height Hr can be slightly decreased by providing a surface assembly (flip-chip) between chip 3 and wafer 5. In this case, chip 3 is connected to wafer 5, not by conductive wires, but by balls or contact pads arranged under chip 3. It is thus possible to do away with protection resin 13 (which is substantially used, in the example of FIG. 1, to protect wires 11), and thus to decrease height Hr.

However, in practice, height Hr of the central island containing chip 3 is at least from 250 to 300 μm. Given the fact that balls 7 are partially crushed during their assembly, it is not possible to use balls having a diameter below from 350 to 450 μm, corresponding to an inter-ball step (from center to center) on the order of 650 μm.

FIGS. 2A to 2F are cross-section views schematically showing steps of an example of an assembly method which has been provided to enable the use of conductive balls of smaller diameter.

FIG. 2A illustrates a device 1, corresponding to lower device 1 of FIG. 1. As previously, device 1 comprises a semiconductor chip 3, encapsulated in a package.

The package of device 1 comprises, in its lower portion, a support wafer 5 having chip 3 assembled on its upper surface, and, in its upper portion, a protection resin 13 in which are embedded the upper and lateral surfaces of chip 3 and conductive wires 11 providing the connections of chip 3 to wafer 5. In an initial step of the assembly method, conductive balls 7 are attached to contacting areas of the upper surface of wafer 5, around the central island formed by chip 3 and resin 13.

FIG. 2B illustrates a step during which a resin layer 21, of a height greater than the height of balls 7, is formed on the entire upper surface of device 1. At the end of this step, balls 7 are embedded in layer 21 and are thus no longer accessible from the upper surface of device 1.

FIG. 2C illustrates a step during which openings are formed in resin layer 21 in front of balls 7, by laser etching, to clear the access to the upper portion of balls 7.

FIG. 2D illustrates a step during which a device 2, corresponding to upper device 2 of FIG. 1, is bonded to device 1. As previously, device 2 comprises a semiconductor chip 4 encapsulated in a package. The package of device 2 comprises, in its lower portion, a support wafer 15 having chip 4 assembled on its upper surface, and, in its upper portion, a protection resin 17 in which are embedded the upper and lateral surfaces of chip 4 and the conductive wires providing the connections of chip 4 to wafer 15. Prior to the bonding of device 2 to device 1, conductive balls 7′ are attached to the lower surface of wafer 15, and are intended to contact balls 7 of lower device 1. The cavities formed in resin layer 21 at step 2C enable, during the bonding, to properly guide and align balls 7′ with respect to balls 7.

FIG. 2E illustrates the final assembly, after the bonding of device 2 on device 1 and after the assembly has been heated to weld balls 7′ to balls 7. It should be noted that balls 9 may be attached to the lower surface of wafer 5 of device 1, to provide connections to an external device (not shown), for example a printed circuit board.

The method illustrated in FIGS. 2A to 2E enables to increase the number of connections per surface area unit between devices 1 and 2 with respect to an assembly of the type described in relation with FIG. 1. In the assembly of FIG. 2E, devices 1 and 2 comprise opposite conductive balls, welded to one another. Thus, for a given ball diameter, height Hb available between the upper surface of support wafer 5 and the lower surface of support wafer 15 is approximately twice greater than in an assembly of the type described in relation with FIG. 1. It is thus possible, for a given height Hr of the central island containing chip 3, to decrease the ball diameter, and thus the inter-ball step with respect to an assembly of the type described in relation with FIG. 1. As an example, the assembly method described in relation with FIGS. 2A to 2E enables, for a height Hr of the central island approximately ranging from 250 to 300 μm, to use balls having a diameter from 200 to 250 μm with an inter-ball step approximately ranging from 400 to 500 μm.

However, a disadvantage of this method is that it uses a long and expensive step of forming of openings in front of conductive balls 7, by laser etching of resin layer 21 (FIG. 2C). Further, after having formed these openings, it is necessary to provide cleaning steps to avoid for residues of resin 21 to prevent the forming of a contact between balls 7 and 7′. Despite these cleaning steps, resin residues may happen not to be removed, which adversely affects the quality of the electric contact between balls 7 and 7′.

### BRIEF SUMMARY

One embodiment provides a method for forming an assembly comprising, stacked on each other, first and second devices with semiconductor components comprising opposite conductive balls, this method overcoming at least some disadvantages of existing solutions.

One embodiment provides such a method which does not require providing a step of forming of local openings, in a resin layer where conductive balls are embedded.

One embodiment provides such a method enabling to improve the quality of the electric contacts between the first and second devices with respect to current methods.

One embodiment provides an assembly comprising, stacked on each other, first and second devices with semiconductor components.

One embodiment provides a method for forming an assembly comprising, stacked on each other, first and second devices with semiconductor components comprising opposite conductive balls, this method comprising the steps of:
a) forming, on the first device, at least one resin pattern having the shape of a frame or a portion of a frame, close to at least some of the conductive balls by a non-zero distance smaller than or equal to half the ball diameter, and of a height greater than the ball height; and
b) bonding the second device to the first device, by using said at least one pattern to guide the balls of the second device towards the corresponding balls of the first device.

According to one embodiment, said at least one pattern has the shape of a frame surrounding all the balls of the first device.

According to one embodiment, said frame comprises, on its inner edge, crenellations penetrating, in top view, into the space separating neighboring balls of the first device.

According to one embodiment, the height of said at least one pattern is in the range of 130 to 170% of the height of the balls of the first device.

According to one embodiment, the balls of the first device are arranged in a ring on a surface of this device.

According to one embodiment, on the surface of the first device comprising the balls arranged in a ring is formed an island containing a semiconductor chip located, in top view, within the ring.

According to one embodiment, the thickness of said island is greater than the height of the balls of the first device.

One embodiment provides an assembly comprising, stacked on each other, first and second devices with semiconductor components comprising opposite conductive balls, comprising, on the first device, at least one resin pattern having the shape of a frame or a portion of a frame, close to at least some of the conductive balls by a non-zero distance smaller than or equal to half the ball diameter, and of a higher greater than the ball height.

According to one embodiment, said at least one pattern has the shape of a frame surrounding all the balls of the first device.

The foregoing and other features and advantages will be discussed in detail in the following non-limiting description of specific embodiments in connection with the accompanying drawings.

### BRIEF DESCRIPTION OF THE SEVERAL VIEWS OF THE DRAWINGS

FIG. 1, previously described, is a cross-section view schematically showing an assembly comprising, stacked on each other, first and second devices with semiconductor components;

FIGS. 2A to 2E, previously described, are cross-section views schematically showing steps of a method for forming an assembly comprising, stacked on each other, first and second devices with semiconductor components comprising opposite conductive balls;

FIGS. 3A to 3D are cross-section views schematically showing steps of an embodiment of a method for forming an assembly comprising, stacked on each other, first and second devices with semiconductor components comprising opposite conductive balls;

FIGS. 4A to 4F are simplified top views showing embodiments of the lower device used in the method described in relation with FIGS. 3A to 3D.

### DETAILED DESCRIPTION

For clarity, the same elements have been designated with the same reference numerals in the different drawings and, further, as usual in the representation of integrated circuits, the various drawings are not to scale.

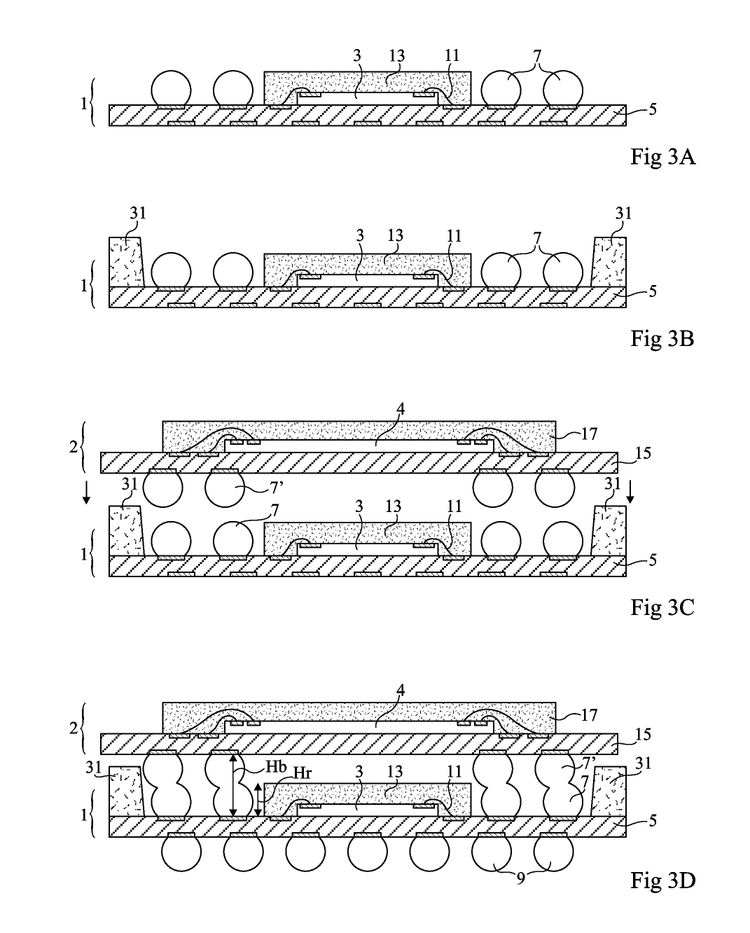

FIGS. 3A to 3D are cross-section views schematically showing steps of an embodiment of a method for forming an assembly comprising, stacked on each other, first and second devices with semiconductor components comprising opposite conductive balls.

FIG. 3A illustrates a lower device 1, for example corresponding to lower device 1 of FIG. 1. As previously, device 1 comprises a semiconductor chip 3, encapsulated in a package. The package of device 1 comprises, in its lower portion, a support wafer 5 having chip 3 assembled on its upper surface and, in its upper portion, a protection resin 13 in which are embedded the upper and lateral surfaces of chip 3 and conductive wires 11 providing the connections of chip 3 to wafer 5. Conductive balls 7 are attached to contacting areas of the upper surface of wafer 5. In the present example, in top view, balls 7 are arranged in a ring around chip 3.

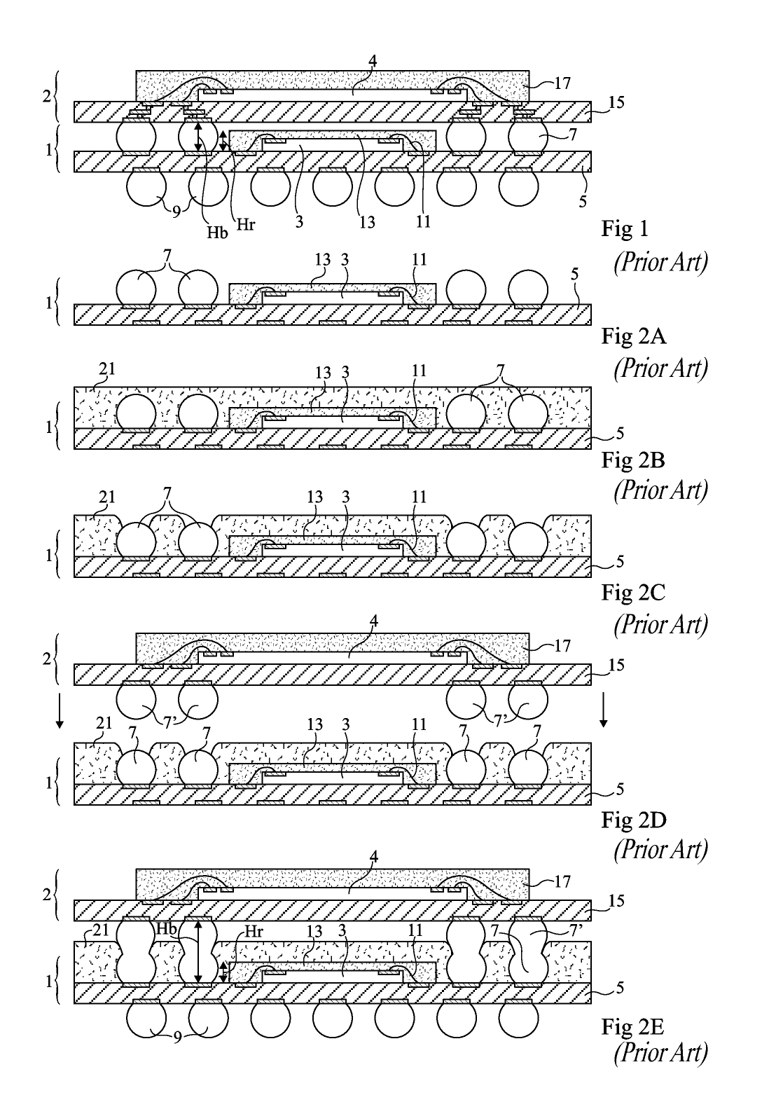

FIG. 3B illustrates a step during which a resin pattern 31, of a height greater than the height of balls 7, is formed by molding on the upper surface of support wafer 5. In this example, in top view, pattern 31 has the shape of a frame surrounding the assembly of balls 7. As an example, the height of pattern 31 is approximately in the range of 110% to 190%, and preferably of 130% to 170%, of the height of balls 7. Pattern 31 is close to balls 7 forming the external periphery of ball ring 7, by a distance d smaller than or equal to half the diameter of balls 7. In practice, distance d is selected to be as small as possible, taking into account manufacturing constraints and especially the thickness of the mold wall. One will note that the distance d between the resin pattern 31 and the balls 7 is substantially non-zero since it is at least equal to the thickness of the mold wall. In other words, none of the balls 7 of device 1 is in contact with the resin pattern 31. Conversely to the method described in relation with FIGS. 2A to 2E, in the provided method, resin 31 does not cover balls 7.

FIG. 3C illustrates a step during which a device 2, for example corresponding to upper device 2 of FIG. 1, is bonded to device 1. In this example, as previously, device 2 comprises a semiconductor chip 4 encapsulated in a package. The package of device 2 comprises, in its lower portion, a support wafer 15 having chip 4 assembled on its upper surface and, in its upper portion, a protection resin 17 in which are embedded the upper and lateral surfaces of chip 4 and the conductive wires providing the connections of chip 4 to wafer 15. Prior to the bonding of device 2 to device 1, contact balls 7′ intended to contact balls 7 of lower device 1 are attached to the lower surface of wafer 15. During the bonding of device 2 to device 1, resin frame 31 enables to properly guide and align balls 7′ with respect to balls 7. Balls 7′ are capable of directly abutting against the inner lateral walls of frame 31, thus ensuring the proper alignment of the balls, and especially avoiding for a ball 7′ of device 2 to short-circuit two balls 7 of device 1.

FIG. 3D illustrates the final assembly, after the bonding of device 2 on device 1 and after the assembly has been heated to weld balls 7′ to balls 7. Balls 9 may be attached to the lower surface of wafer 5 of device 1, to provide connections to an external device (not shown), for example a printed circuit board.

It should be noted that resin pattern 31 may take other forms than a frame surrounding ball assembly 7.

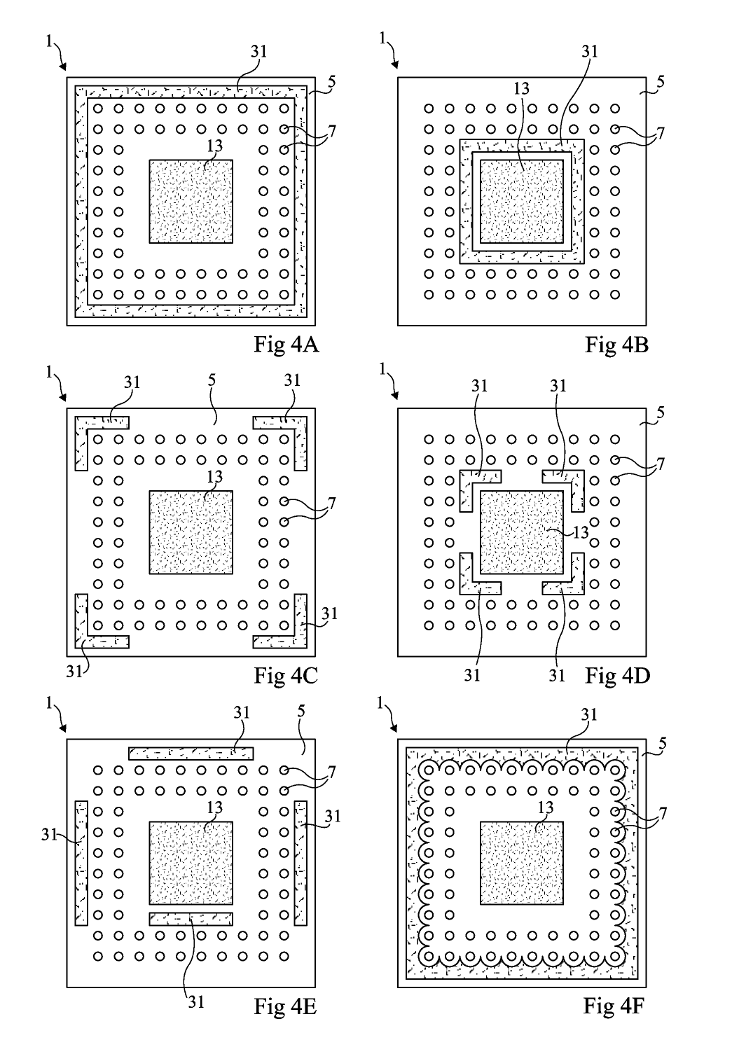

FIGS. 4A to 4F are simplified top views of a device 1 of the type described in relation with FIG. 3B, showing various shapes likely to be taken by resin pattern 31.

FIG. 4A illustrates an example corresponding to FIG. 3B, in which resin pattern 31 has the shape of a frame surrounding balls 7, at a distance from the external edge of ball ring 7 smaller than or equal to the half-diameter of a ball.

FIG. 4B illustrates an example in which resin pattern 31 has the shape of a frame formed within ball ring 7, at a distance from the inner edge of ball ring 7 smaller than or equal to the half-diameter of a ball.

FIG. 4C illustrates an example in which resin pattern 31 has the shape of corners parallel to the external corners of ball ring 7, at a distance from the external corners of ball ring 7 smaller than or equal to the half-diameter of a ball.

FIG. 4D illustrates an example in which resin pattern 31 has the shape of inner corners parallel to the inner corners of ball ring 7, at a distance from ball ring 7 smaller than or equal to the half-diameter of a ball.

FIG. 4E illustrates an example in which resin pattern 31 has the shape of strip portions parallel to external and inner corners of ball ring 7, at a distance from the corners of ball ring 7 smaller than or equal to the half-diameter of a ball.

FIG. 4F illustrates an example in which resin pattern 31 has the shape of a frame surrounding balls 7, this frame having, on its inner edge, crenellations penetrating into the space separating balls 7 from the external edge of ball ring 7.

More generally, it will be within the abilities of those skilled in the art to provide any resin pattern having the shape of a frame or of a portion of a frame, capable of providing a proper alignment of balls 7′ with respect to balls 7, this pattern being close to at least some balls 7 by a non-zero distance smaller than or equal to half the ball diameter. The pattern will especially be selected according to the layout of balls 7. It should further be noted that balls 7 and 7′ may be arranged otherwise than in a ring.

Continuous resin patterns of the type shown in FIGS. 4A and 4F (external frame) and 4B (inner frame), have the advantage over discontinuous patterns (FIGS. 4C, 4D, and 4E) of using only a single resin injection point during the molding.

Further, the resin patterns shown in FIGS. 4A and 4F (external frame at the periphery of wafer 5) have the advantage of stiffening support wafer 5, which enables to avoid any warpage of the structure when the assembly is heated up to weld balls 7 and 7′.

An advantage of the provided method is that it does not require the provision of an expensive step of forming of local openings in a resin layer embedding conductive balls.

Further, the provided method ensures a good quality of the electric contact between balls 7 and 7′, no resin residue due to an etching being likely to interpose between corresponding balls 7 and 7′.

Specific embodiments have been described. Various alterations, modifications and improvements will readily occur to those skilled in the art.

In particular, the present disclosure is not limited to the sole devices with semiconductor components of the type described as an example hereabove. The semiconductor chips of devices 1 and/or 2 may for example be connected to their respective patterns by a flip-chip type connection (with no conductive wires and possibly with no protection resin). Further, devices 1 and 2 may each comprise one or several stacked semiconductor chips. More generally, the provided method may be used to assemble all types of devices with semiconductor components comprising opposite conductive balls.

Further, the present disclosure is not limited to the dimensions mentioned as an example in the present description. A method of the type described in relation with FIGS. 3A to 3D and 4A to 4E may especially be used to assemble devices of smaller dimensions, for example, two stacked semiconductor chips comprising opposite conductive balls.

Further, it will of course be within the abilities of those skilled in the art to use the provided method to stack up more than two devices comprising semiconductor components.

Such alterations, modifications, and improvements are intended to be part of this disclosure, and are intended to be within the spirit and the scope of the present disclosure. Accordingly, the foregoing description is by way of example only and is not intended to be limiting. The present disclosure is limited only as defined in the following claims and the equivalents thereto.

The various embodiments described above can be combined to provide further embodiments. These and other changes can be made to the embodiments in light of the above-detailed description. In general, in the following claims, the terms used should not be construed to limit the claims to the specific embodiments disclosed in the specification and the claims, but should be construed to include all possible embodiments along with the full scope of equivalents to which such claims are entitled. Accordingly, the claims are not limited by the disclosure.

1. A method, comprising:
forming an integrated circuit assembly, the forming including:
forming, on a first device a resin pattern having a shape of a frame or of a portion of a frame separated from first conductive balls by a distance less than or equal to half a diameter of one of the first conductive balls, and of a height greater than a height of the first conductive balls;
stacking a second device on the first device; and
bonding the second device to the first device , by using said at least one pattern to guide second conductive balls of the second device towards the corresponding first conductive balls of the first device.

2. The method of claim 1, wherein said at least one pattern surrounds all the balls of the first device.

3. The method of claim 2, wherein said frame comprises, on its inner edge, crenellations penetrating into spaces separating neighboring first conductive balls of the first device.

4. The method of claim 1, wherein the height of said at least one pattern is in a range of 130% to 170% of the height of the first conductive balls of the first device.

5. The method of claim 1, wherein the first conductive balls of the first device are arranged in a ring on a surface of the first device.

6. The method of claim 5, wherein, on the surface of the first device is formed an island containing a semiconductor chip located, in top view, within the ring.

7. The method of claim 6, wherein the thickness of said island is greater than the height of the balls of the first device.

8. An assembly comprising:
a first device including a first semiconductor component, first conductive balls adjacent to the first semiconductor component, and a resin pattern, having a shape of a frame or of a portion of a frame, close to and separated from at least some of the first conductive balls by a distance smaller than or equal to half of a diameter of one of the first conductive balls, the resin pattern having a height greater than a height of the first conductive balls; and
a second device stacked on the first device, the second device including a second semiconductor component and second conductive balls, the second conductive balls being on a surface of the second device opposite the second semiconductor component, each second conductive ball being in contact with a respective one of the first conductive balls.

9. The assembly of claim 8, wherein said at least one pattern surrounds all of the first conductive balls of the first device.

10. The assembly of claim 8 wherein said at least one pattern includes a plurality of separate resin portions.

11. A method comprising:
forming first solder balls on a first substrate adjacent a first integrated circuit die on the first substrate;
forming a resin guide structure on the first substrate adjacent the first solder balls;
forming second solder balls on a second substrate; and
fixing a second substrate to the first substrate, the fixing including:
using as an alignment guide the resin guide structure; and
coupling the second solder balls to respective ones of the first solder balls.

12. The method of claim 11 comprising positioning the resin guide structure to surround the first solder balls.

13. The method of claim 11 comprising positioning the resin guide structure between the first integrated circuit die and the first solder balls.

14. The method of claim 11 wherein forming the resin guide structure comprises forming multiple separate resin guide structure portions.

15. The method of claim 11 comprising spacing the resin guide structure from one of the first solder balls by a distance less than half a width of the one of the first solder balls.

16. The method of claim 11 wherein a height of the resin guide structure is greater than a height of the first solder balls.

17. A device comprising:
a first substrate;
a first integrated circuit die positioned on the first substrate;
first solder balls positioned on the first substrate adjacent the first integrated circuit die;
a resin alignment guide frame on the first substrate adjacent the first solder balls;
a second substrate stacked on the first substrate;
second solder balls attached to the second substrate, each second solder ball being in contact with a respective one of the first solder balls, the resin alignment guide frame being to align the second solder balls with respective ones of the first solder balls.

18. The device of claim 17 comprising a second integrated circuit die on a surface of the second substrate opposite the second solder balls.

19. The device of claim 18 wherein the resin guide structure is spaced from one of the first solder balls by a distance less than half a width of the one of the first solder balls.

20. The device of claim 17 wherein the resin guide structure surrounds the first solder balls.

21. The device of claim 17 wherein the resin guide structure is positioned between the first integrated circuit die and the first solder balls.

22. The device of claim 17 wherein the resin alignment guide structure includes a plurality of separated resin structures.
